(19) United States
(12) Patent Application Publication
(10) Pub. No.: US 2008/0207005 A1
(43) Pub. Date: Aug. 28, 2008

(54) Wafer Cleaning After Via-Etching

(75) Inventor: Janos Farkas, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/816,036

(22) PCT Filed: Feb. 2, 2005
(86) PCT No.: PCT/EP06/02849

§ 371 Date: Apr. 8, 2008

(30) Foreign Application Priority Data
Feb. 15, 2005 (EP) PCT/EP2005/001510

(51) Int. Cl. H01L 21/306

(52) U.S. Cl. 438/745; 257/E21.228

(57) ABSTRACT

When a semiconductor wafer bears porous dielectric materials it is still possible to perform post-via-etch cleaning of the wafer using aqueous cleaning fluids if, before and/or simultaneously with application of the aqueous cleaning fluid(s), a water-soluble organosilane or like passivation material is used to form a passivation layer on the porous dielectric material.

The present invention relates to the processing of semiconductor wafers and the like, and more particularly to a technique for cleaning wafers after dry etching of vias or trench-like structures.

As features sizes in integrated circuits become progressively smaller, it has become increasingly important to reduce the resistance-capacitance delay (RC delay) attributable to the interconnects used in the circuit. In order to reduce this RC delay, it has been proposed that advanced interconnects should have a reduced dielectric constant (k), notably, that these interconnects should be made of low-k materials. As a first step, carbonated silicon dioxide (SiOC) films had been introduced in the 90-120 nm technology nodes. Currently the k-value is being further improved by introducing pores in these carbonated silicon dioxide films.

Incidentally, in the present document the expression “carbonated silicon dioxide films” and the general formula “SiOC” are used to designate silicon dioxide films that have been formed or treated so as to have carbon therein (e.g. by using CH₃SiH₃ in place of the SiH₄ that is often used as a precursor in the formation of a silicon dioxide layer). In other documents such films are sometimes referred to as carbon-doped silicon dioxide films.

These materials are being developed by several vendors, using chemical vapour deposition or spin-on coating techniques. Several vendors are currently developing CVD deposited films using a porogen approach. With this technology the porogens build into a film and are degassed during the post-treatment, leaving pores in the dielectric films. Applied Materials (Black Diamond IIx; III), Novellus systems (ELK Coral), Trikon (Orion); ASM are amongst the companies working on this approach. Suppliers of materials in the field of spin-on porous dielectrics include Dow Chemicals (SiLK), Rhom and Haas (Zirkon) and JSR.

Any silicon oxide-containing material will have a substantial population of surface hydroxyl (silanol) groups on the surface, which are highly polarized and therefore have a high affinity to water uptake. These sites are generated by the break up of four and six member bulk siloxane (Si—O—Si) bridges at the surface of the material. These siloxane structures at the material surface have an uncompensated electric potential and so can be considered to be “strained”. They will react with moisture to form surface hydroxyl groups. If the material is porous, the surface hydroxyls and the adsorbed water molecule will propagate to the bulk of the material. This will results in increased dielectric constant values and reduced reliability of the film.

A comparable effect occurs for other materials, such as metal oxides, present on the surface of a wafer. The metal ion—oxide bonds located at the surface of the material have an uncompensated electric potential. This leads to a tendency to react with moisture so as to form surface hydroxyl groups. Once again, if the material is porous the surface hydroxyls and adsorbed water molecule will propagate to the bulk of the material and lead to an unwanted increase in dielectric constant.

As mentioned above, carbonated silicon oxide is often used as a porous dielectric material. The carbon-rich surface has a reduced number of strained oxide bonds. Thus, there is a reduced population of surface hydroxyls at the surface of the material.

For carbon-containing porous dielectrics, the sensitivity to water uptake is significantly higher after a dry etch process. The oxidizing plasma reduces the carbon content at the surface of the material and therefore increases the population of surface hydroxyls. As it can be expected, the change in the dielectric constant of these porous materials increases after the dry etch step and there is a need to “restore” the k value of the film. One common technique is to apply a supercritical CO₂ treatment with Hexamethyldisilazane (HMDS).

For the reasons described above, it is important to prevent water uptake if porous dielectric materials are used to form interconnects. Moreover, it has been observed that absorption of water by a porous dielectric could lead to corrosion of Ta-based barriers.

Some potential counter-measures to combat the take-up of water by such porous dielectric materials during manufacture and use of a semiconductor integrated circuit include the above-described “dielectric restoration”, and “pore sealing”. Pore sealing involves prevention of access to the pores in the porous material, for example by modifying the surface of the porous material (e.g. using an organosilane treatment), or by depositing a thin dielectric film on the surface of the porous dielectric layer. The latter has a disadvantage of increasing the k value of the layer.

Now, when a semiconductor integrated circuit is manufactured it is necessary to etch vias or trench-like structures in one or more layers provided on the circuit substrate (wafer). When the vias or trench-like structures are etched, polymer material tends to build up in the via/trench. In addition metallic species (e.g. copper) could be sputtered onto the sidewalls. This organic residues are formed due to the interaction of hydrocarbon etchant gases in the plasma with the substrate material. Thus, it is necessary to perform a cleaning step in order to remove the residual polymer and metallic species, before proceeding to the next stages in the manufacturing process. Traditionally, cleaning to remove such residual polymer would involve the application of aqueous solutions, such as dilute hydrofluoric acid (HF), or organic acids/bases. However, such an approach is not suitable in the case where porous material is present at the surface of the wafer to be cleaned.

If the conventional approach were to be adopted for post-via-etch cleaning of a wafer bearing a porous interconnect layer, the porous dielectric material would adsorb water from the aqueous cleaning fluids. This problem is particularly acute in the case where the dielectric layer has undergone plasma damage during the via/trench-etching process. Besides the negative effect on the dielectric layer's dielectric constant, the adsorbed water can also cause problems during subsequent stages in the manufacture of the circuit, notably degassing and reliability problems.

In some cases, a pore sealing treatment has been applied to the porous dielectric layer after vias have been etched therein. However it has been found that, after cleaning such pore-sealed dielectric layers using conventional water-containing cleaning fluids, there has still been undesirable water adsorption by the dielectric layer.

For example, US2004/023515 proposes to immerse a semiconductor wafer in a silanizing agent (e.g. a silane-coupling agent dissolved in water, ethyl alcohol or hexane) in order to coat the wafer surface and seal pores, and indicates that this process can be performed after via etch. The described process does not mention any post-etch cleaning of the wafer.

In view of the above-mentioned problems, an alternative approach has been proposed for post-via-etch cleaning of a wafer bearing a porous dielectric material. The alternative approach involves applying supercritical carbon dioxide (CO₂) to the etched surface. However, this approach has the disadvantage that it requires investment in new equipment which is at a more experimental stage in development than the cleaning equipment already in widespread use in the semiconductor manufacturing industry.

The present invention provides a method of cleaning a substrate bearing a porous dielectric material and etched vias or trench-like structures, as described in the accompanying claims.

A preferred embodiment of the invention will now be described, by way of example, with reference to the drawings, of which:

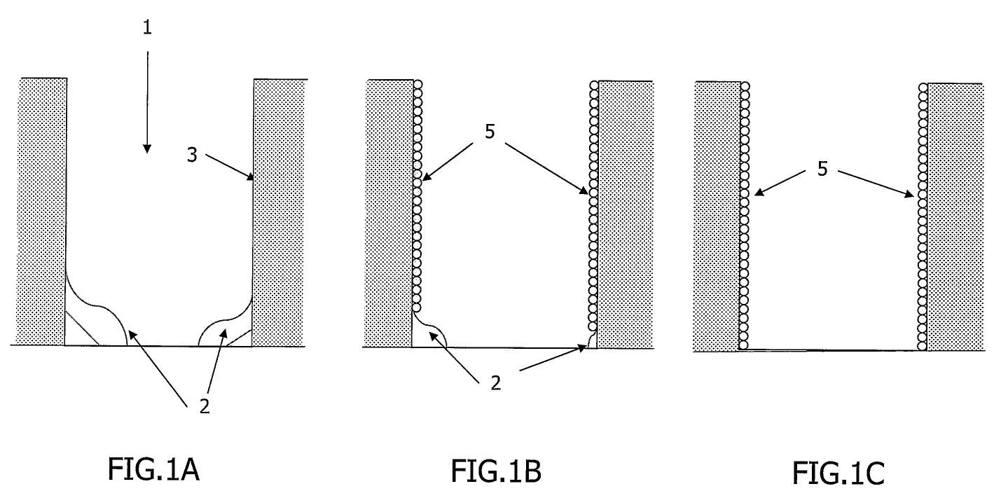

FIG. 1 is a diagram schematically illustrating the main steps in the cleaning method according to the preferred embodiment of the present invention, in which:

FIG. 1A illustrates a trench containing residual polymer and metallic contamination to be removed,

FIG. 1B shows a passivation layer applied to certain surface regions of the trench, and

FIG. 1C illustrates the trench after cleaning; and

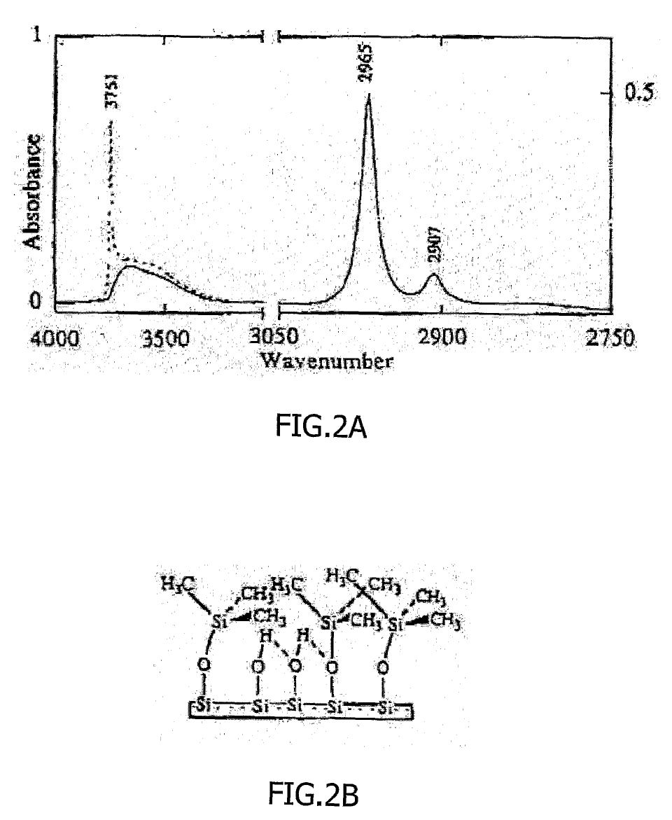

FIG. 2 is a diagram illustrating steric shielding on the surface of a porous dielectric material in the vicinity of an etched via/trench-like structure, in which:

FIG. 2A is a graph representing an absorption spectrum of the porous dielectric material after the surface thereof has been treated using trimethyl dimethyl aminosilane, and

FIG. 2B illustrates how methyl groups from the trimethyl dimethyl aminosilane can prevent access to remaining silanol groups on the porous dielectric surface.

The cleaning method of the preferred embodiment of the present invention will now be described with reference to FIGS. 1 and 2.

In the following description it shall be assumed that the cleaning method is being applied to a semiconductor substrate which has on its surface a porous SiOC layer through which a via has been etched. However, it is to be understood that the present invention is not limited to use on wafers bearing porous SiOC layers, but can be used for wafers bearing other porous dielectrics that are prone to have surface hydroxyls.

The cleaning process aims to remove residual polymer from the via, as well as removing metallic species (e.g. copper) which may have sputtered onto the via side walls during the earlier etch process. FIG. 1A illustrates a via, 1, in which residual polymer, 2, has built up. The via's side walls are defined by a porous SiOC layer 3, and the bottom of the via 1 is defined by the surface of the layer (e.g. copper) underlying the porous layer 3.

The preferred embodiments of the present invention allow traditional aqueous cleaning fluids to be used for removing the polymer and/or metallic species that have built up in the etched vias, trenches or the like during manufacture of the semiconductor integrated circuit. However, porous dielectric materials (e.g. SiOC) on the substrate are protected from contact with the water in the aqueous cleaning fluids because of the application of a passivating material to the surface substantially at the same time as the cleaning fluids are applied.

Typical aqueous, post-etch cleaning fluids with which the passivating material may be mixed include:

amides (e.g. N-methylprrolidinone, dimethylformamide, dimethylacetamide),

alcoholamines (e.g. ethanolamine), amines (e.g. trimethylamine),

diamines (e.g. ethylenediamine and N,N-diethylethylenediamine), triamines (e.g. diethylenetriamine), diamine acids (e.g. EDTA),

organic acids (e.g. acetic, oxalic, glycolic, citric, tartaric, formic acid), ammonium salts of organic acids (e.g. tetramethylammonium acetate),

inorganic acids (e.g. sulphuric acid, phosphoric acid, hydrofluoric acid),

fluoride salts (e.g. ammonium fluoride), bases (e.g. ammonium hydroxide and tetramethyl ammonium hydroxide),

hydroxylamine products, and

inorganic ammonium salts (e.g. ammonium phosphate).

Fluoride salts may be mixed with other components in the post-etch cleaning fluid, e.g. with amines or organic acids. Moreover, the post-etch cleaning fluids with which the passivating agent may be mixed can include a co-solvent in addition to water, for example, alcohols (e.g. ethanol, 2-propanol). Furthermore, as discussed below, surfactants and complexing agents may be included in the post-etch cleaning fluid/passivating agent mix.

According to the preferred embodiment of the present invention, the passivating material is applied to the etched wafer surface and reacts with the surface hydroxyls. This attaches one or more shielding groups present in the passivating material to the surface of the porous dielectric. The gaps between the attached shielding groups are too small to allow water molecules to reach the porous material's surface. Thus the attached groups provide steric shielding.

A wide variety of materials may be used to constitute the passivating material. The important features are that the passivating material:
should include a functional group which reacts with surface hydroxyls,
should include at least one, preferably at least two organic shielding groups, and
after the reaction with the surface should form at least one, preferably at least two shielding layers above the surface

It is also advantageous if the passivating material is water-soluble and the functional group(s) thereof has a sufficiently-fast reaction speed with surface hydroxyls, as explained below. The passivating material may include at least one functional group which may be hydrolysed in water.

In preferred embodiments of the invention, the passivating material is an organosilane and can be represented using the formula:

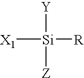

where:
Si is a silicon atom;
X₁ is a first functional group reacting with the surface hydroxyl sites of the porous material;
Y is either:
X₂, a further functional group reacting with the surface hydroxyl sites of the porous material,
H (i.e. hydrogen), or
R₁ an organic apolar group or branch;
   Z is either:
X₃, a further functional group reacting with the surface hydroxyl sites of the porous material,
H (i.e. hydrogen), or
R₂ an organic apolar group or branch;
   R is a carbon-containing, organic apolar group or branch.

In a case where the silicon is bonded to two functional groups, X₁ and X₂, or X₁ and X₃, these two functional groups could be the same or different from each other. In a case where the silicon is bonded to three functional groups, X₁, X₂ and X₃, these three functional groups could all be different, could all be the same, or two out of three could be the same.

Similarly, in a case where the silicon is bonded to two organic apolar groups, R and R₁, or R and R₂, these two organic groups could be the same or different from each other. In a case where the silicon is bonded to three organic apolar groups, R, R₁ and R₂, these three organic groups could all be different, could all be the same, or two out of three could be the same.

It is preferable for each of Y and Z to be a functional group or an organic apolar group. However, it is permissible for Y and/or Z to be H.

It is the organic apolar groups and/or branches of the molecule which will provide the steric shielding of the surface from the hydroxyl groups and water molecules.

The number of organic apolar groups/branches in the molecule depends on how many functional groups (X₁, or X₁ and X₂/X₃, or X₁, X₂ and X₃) are attached to the silicon atom. It should be noted that the organic apolar groups/branches can form multiple shielding layers depending on the selection of those groups/branches as illustrated below.

Some examples are given below illustrating the impact of the organic apolar groups/branches on the formation of the shielding layers.

### EXAMPLE 1

### R, Y and Z are Methyl Groups

In the case where the silicon atom is connected to one functional group, X₁, and three methyl groups (i.e. Y=Z=R═CH₃) the general structure of the passivating material will be:

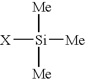

where Me stands for a methyl group.

Such a passivating material produces a single shielding layer on the porous material as shown in FIG. 2B.

### EXAMPLE 2

### R is an iso-propyl group (Y and Z are methyl groups)

In the case where the silicon atom is connected to one functional group, X₁, two methyl groups (i.e. Y=Z=CH₃) and an iso-propyl group (i.e. R=iso-propyl group), a second shielding layer forms on the porous material, above the one formed by the two methyl groups (Y and Z).

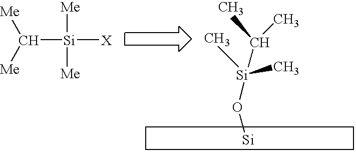

### EXAMPLE 3

### R is a Tert-Butyl Group (Y and Z are Methyl Groups)

In the case where the silicon atom is connected to one functional group, X₁, two methyl groups (i.e. Y=Z=CH₃) and a tert-butyl group (i.e. R=tert-butyl group), once again there is a second shielding layer besides the one formed by the two methyl groups (Y and Z).

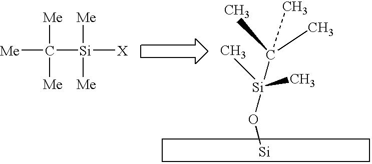

### EXAMPLE 4

### R is a 3,3-dimethylbutyl Group (Y and Z are Methyl Groups)

In the case where the silicon atom is connected to one functional group, X₁, two methyl groups (i.e. Y=Z=CH₃) and a 3,3-dimethylbutyl group (i.e. R=t-BuCH₂CH₂ group, where Bu=butyl), once again a second shielding layer forms on the porous material, above the one formed by the two methyl groups (Y and Z). However, in this case, the spacing between the first and second shielding layers is greater than that which applies in the second and third examples.

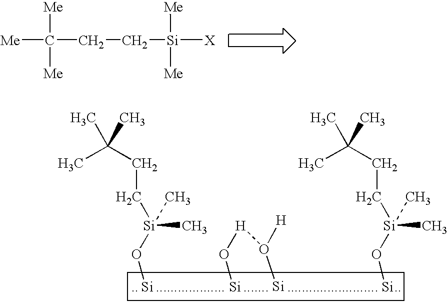

### The Functional Group(s)

The functional group (or groups) Xᵢ in the shielding material is selected such that it will react with hydroxyl groups at the surface of the porous dielectric layer so as to attach one of more shielding layers in the passivating material to that surface. More particularly, the X functional group reacts by the elimination of the surface hydroxyl.

For example, in the case where the porous dielectric is formed of SiOC, a potential passivating material is a trimethyl dimethyl aminosilane:

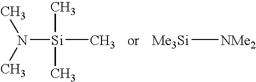

In the case of this trimethyl amino compound, there is one functional group X₁ and it is the amine group, the other three methyl groups connected to the silicon will form a first shielding layer on the porous material.

In the trimethyl dimethyl aminosilane, the amino functional group reacts with a surface silanol in the porous SiOC dielectric so that an NMe₂H molecule is eliminated and an Si—O—Si bond links the porous material's surface to the passivating material, as follows:

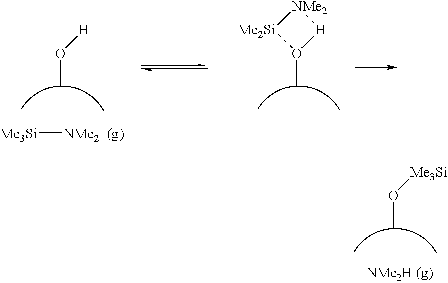

The shielding effect achieved using the trimethyl dimethyl aminosilane is illustrated in FIG. 2. FIG. 2A shows an absorption spectrum of an SiOC layer that has had its surface treated with trimethyl dimethyl aminosilane. As seen in FIG. 2A, a significant absorption peak at wave number 3751, which could be expected to appear if significant quantities of silanols were present, does not appear in the absorption spectrum. The peak visible at wave number 2965 indicates the presence of methyl groups on the surface of the porous dielectric. FIG. 2B illustrates how the shielding methyl groups which become attached to the porous dielectric layer physically prevent access to those silanols which still remain on the surface of the dielectric layer.

In the passivating materials according to the preferred embodiments of the present invention, the functional group(s) Xᵢ could be, for example Cl, Br, I, acryloxy-, alkoxy-, acetamide, acetate-, allyl-, amine-, cyanide, epoxy-; imidazole, mercapto-, methanosulfonate-, sulfonate-, a mono-, bi- or tri-functional amino group (e.g. trifluoroacetamide, and urea groups), etc.

The strength of the bond to the porous dielectric and the speed of the reaction with the surface hydroxyls will be driven by the Xᵢ functional group(s) and the presence or lack of the silicon groups in the passivating material. Organo-silanes form a stronger bond to the surface than non-silicon-containing hydrocarbon chains and so provide a more stable protection for the surface. Accordingly, the preferred embodiments of the invention use organosilanes as the passivating material. However, certain non-silicon-containing materials can also be used as the passivating material, for example, organic amines.

When the passivating material includes more than one functional group, Xᵢ, and the passivating material is applied in a gas phase, it is the functional group which reacts most rapidly which will tend to react with the hydroxyls on the surface of the porous material. When such a passivating material is applied in a liquid phase the reaction scenario is complicated by the fact that certain functional groups hydrolyse. However, there are known water-soluble silanes which have more than one functional group and are stable in water; such materials can satisfactorily functionalize a hydrophilic surface.

The hydrocarbon part of the passivating material molecule will be able to shield the dielectric material from water penetration. In the above example, methyl groups from the trimethyl dimethyl aminosilane serve to form a first shielding layer shielding the surface of the porous dielectric from water.

The length of the hydrocarbon chain, R, as well as the number and type of the hydrocarbon groups R₁, R₂, will determine the shielding efficiency from water penetration.

In the preferred embodiments of the invention, the passivating material includes groups for forming at least two shielding layers at the surface porous dielectric material. The shielding group(s) form a first shielding layer close to the porous dielectric material's surface. The second shielding group(s) form a second shielding layer at a greater distance away from the surface of the porous dielectric.

Any additional shielding groups in the passivating material form additional shielding layers at greater and greater distances away from the surface of the porous dielectric.

Previous studies in other fields have shown that properly chosen organic layers could be efficient to sterically shield non-porous dielectric surfaces from precursors (such as metalorganic compounds), see J. Farkas et al., J. Electrochem. Soc. 141, 3547 (1994). With porous materials it could be expected that the size of the shielding groups R should be proportional to the size of pores.

The effect of R on steric shielding by organosilanes has been studied in the field of HPLC column treatment, see the above-mentioned paper by J. Farkas et al, and in the field of fiber optic protection and selective depositions see K. Szabo et al, Helv. Chimi. Acta. vol. 67 p. 2128, 1984. The Farkas et al paper showed that an organic layer with about 25 Angstroms thickness can be very efficient for steric shielding of a surface from water penetration, even at elevated temperatures. In the case of using passivating materials for steric shielding of a porous dielectric surface, the length of the hydrocarbon chain can be easily adjusted to optimize the efficiency of steric shielding to the pore size of the dielectric.

According to the preferred embodiments of the invention, the organic apolar group(s) attached to the silicon atom are selected from: methyl, ethyl, propyl, butyl, phenyl, pentafluorophenyl, thexyl, and allyl.

In the preferred embodiment of the present invention illustrated in FIG. 1, after the via-etching step the passivating material, e.g. an organosilane, is applied to the surface of the substrate in a preliminary-treatment step. At locations where there is no polymer build up, the applied organosilane reacts with the adsorbed water, or with the silanol-covered SiOC surface layer 3, to form a passivation layer 5 including at least one shielding layer on the SiOC layer 3. FIG. 1B shows the passivation layer 5 covering the SiOC surface layer 3. The applied organosilane does not interact with the residual polymer 2 and, thus, does not impede its removal later on.

Any convenient technique can be used for applying the passivating material to the wafer in the preliminary treatment step. For example, the porous material can be subjected to a surface treatment with organosilanes, to seal the pores therein, in the vapour phase or liquid phase. The benefit of this preliminary step is that the porous surface is already pre-treated before it gets to the aqueous cleaning phase.

If the preliminary treatment of the porous dielectric with the passivating material is performed with an organosilane in the liquid phase, the organosilane will often be highly-diluted in water, with some addition of alcohols (to enhance solubility). If the preliminary treatment of the porous dielectric with the passivating material is performed with an organosilane in the vapour phase, the organosilane could be used with a carrier gas, such as N₂ or Ar, if necessary. The preferred temperature for the preliminary treatment in the liquid phase is between 25-80° C. and the process time is 30 s to 10 min. In the vapour phase the process temperature can be higher, e.g. 150° C. Moreover, the temperature may be limited by the stability of the silane being used (some are stable at temperatures over 300° C. but most are only stable at lower temperatures).

In the cleaning method according to the preferred embodiment of the invention, by formation of the passivation layer 5 it is possible to protect the majority of the porous SiOC surface from water adsorption and penetration. Thus, it could be envisaged to use conventional aqueous cleaning fluids for removal of the residual polymer 2 (and residual metallic species) from the trench 1.

However, after the preliminary treatment step the passivation layer 5 does not cover the entirety of the SiOC surface layer 3. There are locations on the SiOC surface 3 where it bears residual polymer 2. The present inventor has realized that, at the time when a water-containing cleaning fluid removes the residual polymer 2, the freshly-exposed portions of the SiOC surface layer 3 are then liable to absorb water.

According to the preferred embodiments of the invention, the chemicals used for cleaning the via/trench 1 are mixed with more of the above-described passivating material. Thus, if the reaction speed of the functional group(s) Xᵢ in the passivating material is sufficiently fast, as soon as the polymer is removed from a particular portion of the trench by the cleaning fluid, the silanols on the surface of the underlying porous SiOC will react with the passivating material and be covered by the protective organic monolayer before water can be adsorbed. It will be seen that, for this purpose, it is important for the reaction speed of the functional group(s) Xᵢ with the surface silanols (or other surface hydroxyls) to be sufficiently fast for the surface silanols to become shielded before significant quantities of water have been adsorbed from the water-containing cleaning fluid(s).

If the passivating material is a water-soluble organosilane, it can mixed with the cleaning fluid(s) ahead of application thereof to the wafer. However, if the passivating material consists of an organosilane which is traditionally considered not to be water-soluble, notably because of its short pot life (shelf life) when mixed with water, it can be still be used in certain embodiments of the present invention. More particularly, if the organosilane has a short pot life when mixed with water, mixing of the organosilane and the cleaning fluid(s) can be accomplished at, or in the immediate vicinity of, the cleaning tool (i.e. just before application to the wafer).

In general, there is a wider selection of organosilanes possible for the preliminary treatment step than for the cleaning step, since the passivating material used in the preliminary treatment step does not require compatibility with aqueous media.

When the functional group on the passivating material is basic (e.g. the passivating material is a silane having an amino functional group), then it is advantageous to mix the passivating material with a post-etch cleaning fluid which is itself a base, e.g. an amine, tetramethyl ammonium hydroxide, etc.

Similarly, when the functional group on the passivating material is acidic, then it is advantageous to mix the passivating material with a post-etch cleaning fluid which is itself acidic, e.g. diluted HF.

Process conditions for one example of a typical cleaning step according to the preferred embodiments of the present invention are:
applied cleaning mixture=a water-soluble organosilane mixed with an organic acid (or highly diluted aqueous HF), with optional chelating agent and/or surfactant.
process temperature=25-80° C., and
process time=30 s to 10 min

The cleaning step can be applied in various kinds of known post-etch cleaning apparatus (e.g. spray-type apparatus, immersion-type apparatus, etc.). As in conventional post-etch cleaning processes, typically one or more rinse steps will be performed after application of the post-etch cleaning fluid/passivating material mixture to the wafer. Rinse steps of this type will generally use rinsing fluids such as deionized water. The process conditions may vary from those given, as an example, above. Typically, the duration of the cleaning step will be in the range from approximately 1 minute to approximately 20 minutes.

As shown in FIG. 1C, after the residual polymer 2 (and metallic residues) has been removed, the via 1 is clean and the sidewalls thereof are covered by the passivation layer 5. The pores in the porous dielectric layer 3 are sealed by the passivation layer 5.

As indicated above, if desired, during the cleaning process of the present invention a complexing or chelating agent may be used, in order to remove metallic species. These reagents should be added into the passivating material/cleaning fluid mix, so as to be able to be processed in a common series of steps. Common complexing agents include ethylenediamine tetraacetic acid (EDTA) and its derivatives and organic acids.

Similarly, surfactants can be included in the mix of cleaning chemicals. A wide variety of surfactants can be used. It can be advantageous to use as a surfactant block co-polymers built from blocks of polyethyleneoxide and polypropyleneoxide. These two groups are efficiently absorbing on both hydrophobic and hydrophilic surfaces, and the length and ratio of each group present in the block co-polymer can easily be tailored to the application.

The cleaning method according to the preferred embodiment of the invention enables porous dielectric materials to be cleaned without needing to resort to the use of new equipment. More particularly, it is a simple matter to modify existing post-via-etch “wet” cleaning equipment so that it can implement the cleaning method of the present invention. This is much cheaper than implementing a method using supercritical CO₂.

Moreover, the cleaning method according to the preferred embodiment of the invention both enables the porous dielectric material to be protected from aqueous cleaning fluids and seals the pores in the dielectric material, avoiding the need for a separate pore-sealing or dielectric-restoration step. By inhibiting the uptake of water by the porous dielectric material, the cleaning method of the preferred embodiment of the present invention improves reliability of the finished product and increases the yield of the overall manufacturing process.

By passivating the surface (notably etched side walls) of a porous dielectric, the cleaning method according to the preferred embodiment of the present invention helps to reduce delamination later, as well as avoiding a potential increase in dielectric constant.

Although the present invention has been described above with reference to certain particular preferred embodiments, it is to be understood that the invention is not limited by reference to the specific details of those preferred embodiments. More specifically, the person skilled in the art will readily appreciate that modifications and developments can be made in the preferred embodiments without departing from the scope of the invention as defined in the accompanying claims.

For example, although the preferred embodiment of the cleaning method according to the present invention has been described in terms of cleaning via or trench-like structures etched in layers on a substrate including a layer of porous SiOC, the inventive method is applicable more generally to the post-via-etch cleaning of wafers bearing other porous materials that are prone to surface hydroxyl formation.

Similarly, although the above description of the preferred embodiment of the method according to the invention referred to use of aqueous HF or organic acids for cleaning residual polymer from a via, it is to be understood that any other convenient cleaning fluid comprising water can be used.

Furthermore, although the preferred embodiment of the invention was discussed above in terms of cleaning residual polymer (and residual metallic species) from a via, it is to be understood that the invention is applicable in general to the cleaning of etched structures (vias, trenches, etc.).

Moreover, in the cleaning method according to the present invention it is not essential to include a preliminary treatment step of the porous dielectric with a passivating material. Even if there is no preliminary treatment step, the porous dielectric can be protected from absorbing water during the post-via-etch-cleaning, by mixing passivating material with the cleaning fluid(s) applied to the semiconductor wafer.

1. A method of post-etch cleaning a semiconductor substrate having at least one structure etched therein and a region of porous dielectric material, said porous dielectric material being prone to formation of hydroxyls at the surface thereof in the presence of moisture, the method comprising the steps of:
applying to the substrate one or more cleaning fluids adapted to remove post-etch residues, at least one of the applied cleaning fluids comprising water; and
applying to the substrate a passivating material adapted to react with hydroxyls on the surface of the porous dielectric material whereby to form at least one shielding layer on said surface of the porous dielectric material, said at least one shielding layer serving to shield the porous dielectric material from water;
wherein the passivating material is applied to the substrate during the application of said one or more cleaning fluids to the substrate.

2. The cleaning method of claim 1, wherein said passivating material is mixed with the cleaning fluid(s) applied to the substrate.

3. The cleaning method of claim 1, wherein a further passivating material is applied to the substrate in a preliminary treatment step preceding the application of said one or more cleaning fluids to the substrate, said further passivating material being the same as, or different from, the passivating material applied to the substrate during the step of applying cleaning fluid(s) to the substrate.

4. The cleaning method of claim 1, wherein the passivating material is an organosilane according to the general formula: 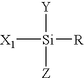
where:
Si is a silicon atom;
X₁ is a first functional group reacting with the surface hydroxyl sites of the porous material;
Y is either:
X₂, a further functional group reacting with the surface hydroxyl sites of the porous material,
H (i.e. hydrogen), or
R₁ an organic apolar group or branch;
Z is either:
X₃, a further functional group reacting with the surface hydroxyl sites of the porous material,
H (i.e. hydrogen), or
R₂ an organic apolar group or branch;
R is a carbon-containing, organic apolar group or branch.

5. The cleaning method of claim 4, wherein the passivating material is an organosilane including shielding groups for forming at least two shielding layers.

6. The cleaning method of claim 5, wherein said organosilane is water-soluble.

7. The cleaning method of claim 5, wherein said organosilane has a short pot life when mixed with water, and comprising the step of mixing the organosilane with the cleaning fluid(s) substantially at the point of application of the cleaning fluid(s) to the substrate.

8. The cleaning method of claim 4, wherein the passivating material includes:
at least one functional group selected from: Cl, Br, I, acryloxy-, alkoxy-, acetamide, acetate-, allyl-, amine-, cyanide, epoxy-; imidazole, mercapto-, methanosulfonate-, sulfonate-, trifluoroacetamide, and urea groups;
and at least one organic apolar group selected from: methyl, ethyl, propyl, butyl, phenyl, pentafluorophenyl, thexyl, and allyl.

9. The method of claim 1, wherein the porous dielectric material comprises SiOC.

10. The cleaning method of claim 1, and comprising the step of applying a complexing or chelating agent to the substrate, whereby to remove metallic species therefrom, during the step of applying one or more cleaning fluids to the substrate.

11. The cleaning method of claim 1, and comprising the step of applying a surfactant to the substrate during the step of applying one or more cleaning fluids to the substrate.

12. The cleaning method of claim 2, wherein a further passivating material is applied to the substrate in a preliminary treatment step preceding the application of said one or more cleaning fluids to the substrate, said further passivating material being the same as, or different from, the passivating material applied to the substrate during the step of applying cleaning fluid(s) to the substrate.

13. The cleaning method of claim 2, wherein the passivating material is an organosilane according to the general formula: 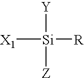
where:
Si is a silicon atom;
X₁ is a first functional group reacting with the surface hydroxyl sites of the porous material;
Y is either:
X₂, a further functional group reacting with the surface hydroxyl sites of the porous material,
H (i.e. hydrogen), or
R₁ an organic apolar group or branch;
Z is either:
X₃, a further functional group reacting with the surface hydroxyl sites of the porous material,
H (i.e. hydrogen), or
R₂ an organic apolar group or branch;
R is a carbon-containing, organic apolar group or branch.

14. The cleaning method of claim 3, wherein the passivating material is an organosilane according to the general formula: 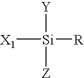
where:
Si is a silicon atom;
X₁ is a first functional group reacting with the surface hydroxyl sites of the porous material;
Y is either:
X₂, a further functional group reacting with the surface hydroxyl sites of the porous material,
H (i.e. hydrogen), or
R₁ an organic apolar group or branch;
Z is either:
X₃, a further functional group reacting with the surface hydroxyl sites of the porous material,
H (i.e. hydrogen), or
R₂ an organic apolar group or branch;
R is a carbon-containing, organic apolar group or branch.

15. The method of claim 2, wherein the porous dielectric material comprises SiOC.

16. The method of claim 3, wherein the porous dielectric material comprises SiOC.

17. The cleaning method of claim 2, and comprising the step of applying a complexing or chelating agent to the substrate, whereby to remove metallic species therefrom, during the step of applying one or more cleaning fluids to the substrate.

18. The cleaning method of claim 3, and comprising the step of applying a complexing or chelating agent to the substrate, whereby to remove metallic species therefrom, during the step of applying one or more cleaning fluids to the substrate.

19. The cleaning method of claim 2, and comprising the step of applying a surfactant to the substrate during the step of applying one or more cleaning fluids to the substrate.

20. The cleaning method of claim 3, and comprising the step of applying a surfactant to the substrate during the step of applying one or more cleaning fluids to the substrate.
